(19) United States
(12) Patent Application Publication
(10) Pub. No.: US 2007/0128781 A1
(43) Pub. Date: Jun. 7, 2007

(54) Schottky barrier tunnel transistor and method of manufacturing the same

(76) Inventors: Moon Gyu Jang, Daejeon (KR); Seong Jae Lee, Daejeon (KR); Yark Yeon Kim, Daejeon (KR); Chel Jong Choi, Deajeon (KR); Myung Sim Jun, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/502,948

(22) Filed: Aug. 11, 2006

(30) Foreign Application Priority Data
Dec. 7, 2005 (KR) 10-2005-0119010

(51) Int. Cl. H01L 21/338

(52) U.S. Cl. 438/181

(57) ABSTRACT

Provided are a Schottky barrier tunnel transistor and a method of manufacturing the same. The method includes the steps of: preparing a substrate; forming an active silicon layer on the substrate; forming a gate insulating layer on a region of the silicon layer; forming a gate electrode on the gate insulating layer; implanting ions into the silicon layer on which the gate insulating layer is not formed; and annealing the ion-implanted silicon layer. Accordingly, it is possible to manufacture the Schottky barrier tunnel transistor having stable characteristics and high performance by implanting the ions into the silicon layer using an ion implantation method and then annealing the silicon layer to form metal-silicide.

### CROSS-REFERENCE TO RELATED APPLICATION

This application claims priority to and the benefit of Korean Patent Application No. 2005-119010, filed Dec. 7, 2005, the disclosure of which is incorporated herein by reference in its entirety.

### BACKGROUND

1. Field of the Invention

The present invention relates to a Schottky barrier tunnel transistor and a method of manufacturing the same, and more particularly, to a Schottky barrier tunnel transistor (SBTT) using metal silicide formed by ion implantation in source and drain regions, and a method of manufacturing the same.

2. Discussion of Related Art

Schottky barrier tunnel transistors, which can effectively control a short channel using a Schottky barrier formed between metal and silicon, are a technology for facilitating use of a high-k dielectric gate thin film and a metal electrode depending on a low temperature process. The operation principle of the Schottky barrier tunnel transistor is based on quantum physics, and therefore the Schottky barrier tunnel transistor can be easily applied to quantum devices in the future.

In recent technology for manufacturing a semiconductor device, a transistor having a short channel of 100 nm or less is manufactured but, as device size is decreased, characteristics of a device based on simple electrical and physical laws meet with quantum mechanical phenomenon, thereby causing problems that have not been raised in conventional art. For example, in the short channel transistor having the channel length of 100 nm or less, leakage current resulting from a short channel effect is greatly increased and therefore must be properly controlled.

Technology for manufacturing the Schottky barrier tunnel transistor was developed to solve such problems which stand in the way of the development of future semiconductor technology. In particular, the Schottky barrier tunnel transistor solves the problem of shallow junction between the electrode and the channel, and even a gate oxide problem.

In general, in order to suppress the short channel effect, a source/drain should have junction depth of one third to one fourth of the channel length. In order to provide such a shallow junction, a method for reducing acceleration voltage using a present ion implantation method is being tested. However, when the junction depth is provided to be 30 nm or less, it is not easy to uniformly control the shallow junction. In particular, in the case where an element having a small atomic number such as phosphorous (P) or boron (B) is used, it is more difficult to uniformly control the shallow junction. Further, as the junction depth is reduced, a parasitic resistance component of the source/drain region using conventional ion diffusion increases. For example, assuming a doping concentration of 1E19 cm⁻³ and a depth of 10 nm, a resistance value exceeds 500 ohm/sq. and therefore causes drawbacks such as signal delay.

In order to overcome such drawbacks, a method of combining rapid thermal annealing (RTA) or laser annealing and solid phase diffusion (SPD) has been proposed, but is not easy to reduce the junction to 10 nm or less. Accordingly, a method of replacing the source/drain region with metal or silicide and reducing a channel length of a Schottky MOSFET to 35 nm or less has been proposed. In this method, a degree of integration can be increased to Terra level. When the source/drain region of the Schottky MOSFET is replaced by metal in the proposed method, surface resistance can be reduced to at least one tenth to one fiftieth of the conventional value, and the operation speed of the device can be improved.

Hereinafter, processes for manufacturing the conventional Schottky barrier tunnel transistor will be schematically described with reference to the accompanying drawings. FIGS. 1A to 1C are side cross-sectional views schematically illustrating processes for manufacturing the conventional Schottky barrier tunnel transistor. In order to manufacture the conventional Schottky barrier tunnel transistor, first, a substrate 100 is prepared. FIG. 1A illustrates a silicon on insulator (SOI) substrate. A buried oxide layer 102 is formed on the SOI substrate 100. Then, an active silicon layer 104 is formed on the substrate 100. A sacrificial layer pattern 106 is formed on the active silicon layer 104. The active silicon layer 104 is formed to a thickness of 50 nm or less such that it is completely silicided in a subsequent process.

Referring to FIG. 1B, a metal layer 108 is formed on the active silicon layer 102 and the sacrificial layer pattern 106. When the Schottky barrier tunnel transistor is manufactured, the metal layer 108 employs erbium (Er) to manufacture an N-type transistor, and platinum (Pt) to manufacture a P-type transistor.

Referring to FIG. 1C, source and drain regions 110 are formed of metal silicide in the active silicon layer 104 at both lower sides of the sacrificial layer pattern 106. In order to form the source and drain regions 110 formed of the metal silicide, the substrate 100 including the metal layer 108, the active silicon layer 104, and the sacrificial layer pattern 106 is annealed and a non-reacted metal layer is removed. Accordingly, the source and drain regions are formed at both lower sides of the sacrificial layer pattern 106. Although not shown, additional processes for forming the gate insulating layer, the gate electrode, and the interlayer insulating layer are then performed.

In the above-described manufacturing process, when the metal layer 108 is formed of platinum to manufacture a P-type device (transistor), platinum (Pt) is stable owing to its high work function and easily silicided so that it is widely used. However, erbium (Er) widely used to manufacture an N-type device is degraded in stability and easily oxidized due to its low work function, so that it is not easy to manufacture.

Further, as described above, in the transistor having a source and drain structure using the impurity diffusion which is formed on an SOI substrate, impurity diffusion toward the channel should be precisely controlled and, as the channel length becomes short, the short channel effect rapidly increases and an energy barrier between a source and a drain is reduced, thereby making it difficult to control leakage current.

### SUMMARY OF THE INVENTION

The present invention is directed to a Schottky barrier tunnel transistor including metal-silicide formed by implanting high-purity ions into a silicon substrate and then annealing the silicon substrate, and a method of manufacturing the same.

The present invention is also directed to a method of manufacturing a Schottky barrier tunnel transistor which forms metal-silicide for manufacturing an N-type transistor having a low Schottky barrier by implanting metal atoms having a low work function into silicon using an ion implantation process in which high purity is easily secured, and then annealing the silicon.

One aspect of the present invention provides a method of manufacturing a Schottky barrier tunnel transistor, the method including the steps of: preparing a substrate; forming an active silicon layer on the substrate; forming a gate insulating layer on a region of the silicon layer; forming a gate electrode on the gate insulating layer; implanting ions into the silicon layer on which the gate insulating layer is not formed; and annealing the ion-implanted silicon layer.

The method may further include the step of, after forming the gate insulating layer, forming sidewall spacers on sidewalls of the gate insulating layer and the gate electrode. The prepared substrate may include a buried insulating oxide layer thereon, and the substrate may be a silicon on insulator (SOI) substrate or a bulk silicon substrate. In the step of forming the silicon layer, the silicon layer may be formed to a thickness of about 50 nm or less. The substrate may have a low concentration of about 10¹⁷ cm⁻³ or less.

In the step of implanting the ions into the silicon layer, one of erbium (Er), ytterbium (Yr), samarium (Sm), and yttrium (Y) may be implanted when an N-type device is manufactured. In the step of annealing the silicon layer, the annealing may be performed at a temperature of about 500° C. to 600° C. In the step of implanting the ions into the silicon layer, platinum (Pt) may be implanted when a P-type device is manufactured. In the step of annealing the silicon layer, the annealing may be performed at a temperature of about 400° C. to 600° C.

Another aspect of the present invention provides a Schottky barrier tunnel transistor including: an active silicon layer formed on a silicon substrate, and having source and drain regions formed of metal-silicide using ion implantation and a channel region between the source and regions; a gate insulating layer formed on the active silicon layer; and a gate electrode formed on the gate insulating layer.

The metal-silicide of the source and drain regions may be formed by implanting different ions depending on an N-type device or a P-type device. In the step of implanting the ions into the silicon layer, one of erbium (Er), ytterbium (Yr), samarium (Sm), and yttrium (Y) may be implanted when an N-type device is manufactured, and platinum (Pt) may be implanted when a P-type device is manufactured. The transistor may further include sidewall spacers formed on sidewalls of the gate insulating layer and the gate electrode.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIGS. 1A to 1C are side cross-sectional views schematically illustrating a conventional method of manufacturing a Schottky barrier tunnel transistor;

FIG. 2 is a schematic block diagram illustrating a method of manufacturing a Schottky barrier tunnel transistor according to the present invention; and

FIGS. 3A to 3E are cross-sectional views illustrating the manufacturing method of FIG. 2.

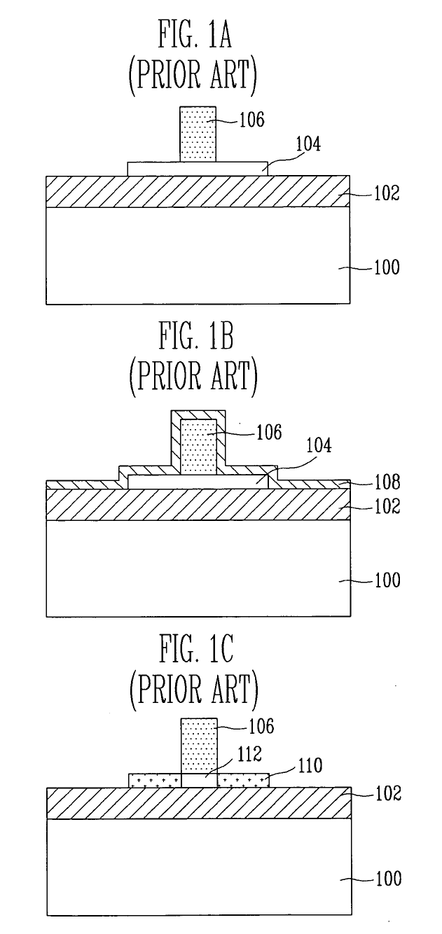

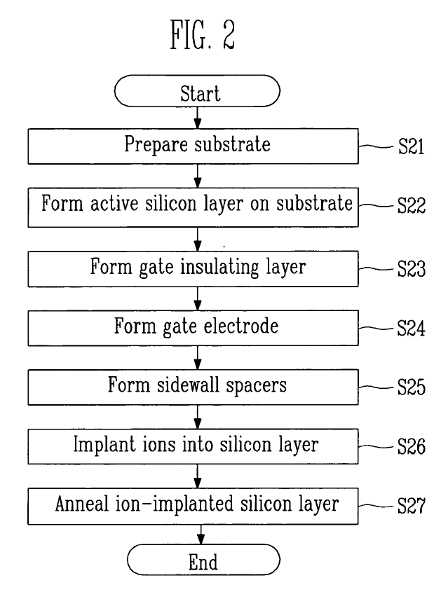

### DETAILED DESCRIPTION OF PREFERRED EMBODIMENTS

Hereinafter, an exemplary embodiment of the present invention will be described in detail. However, the present invention is not limited to the embodiments disclosed below, but can be implemented in various types. Therefore, the present embodiment is provided for complete disclosure of the present invention and to fully inform the scope of the present invention to those ordinarily skilled in the art.

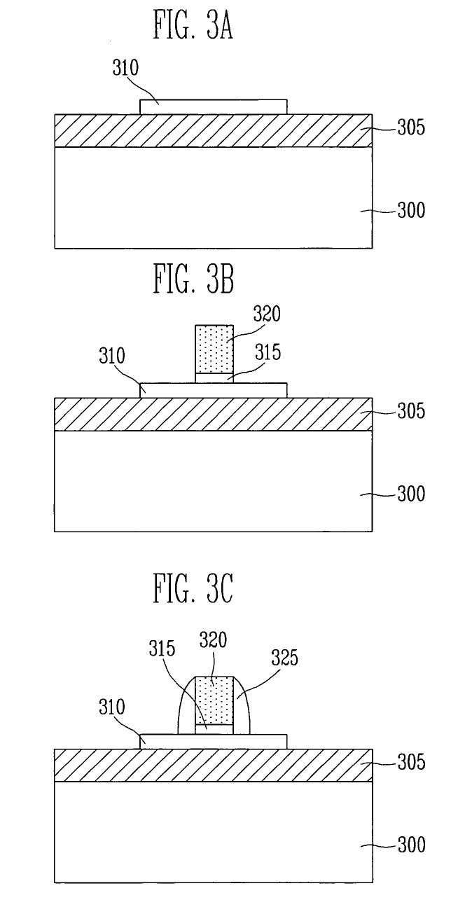

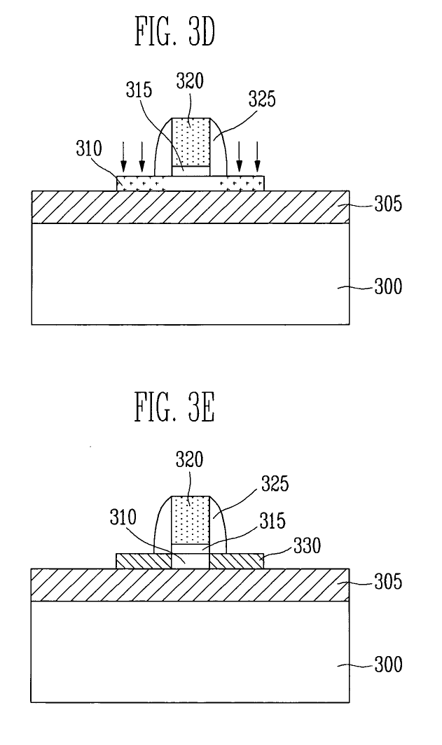

FIG. 2 is a schematic block diagram illustrating a method of manufacturing a Schottky barrier tunnel transistor according to the present invention, and FIGS. 3A to 3E are cross-sectional views illustrating the manufacturing method of FIG. 2.

Referring to FIGS. 2 and 3A, in order to manufacture the Schottky barrier tunnel transistor according to the present invention, a substrate 300 is prepared (S21). The substrate 300 may be a bulk silicon substrate or a silicon on insulator (SOI) substrate. In this embodiment, the SOI substrate is employed. In the case where the substrate 300 is the SOI substrate, a buried oxide layer 305 is formed on the substrate 300.

Next, an active silicon layer 310 is formed on the SOI substrate 300 (S22). In order to form the active silicon layer 310, a silicon layer is deposited on the SOI substrate 300 having the buried oxide layer 305 and then patterned into a desired form. The active silicon layer 310 is patterned by an etching process. In this embodiment, a dry oxidation process is used. The active silicon layer 310 may have a low impurity concentration of about 10E17 or less, or may be formed of an intrinsic semiconductor not containing any impurity. The active silicon layer 310 is formed to a thickness of about 50 nm or less. This is to be completely silicided in a subsequent process (annealing process). In the case where a bulk silicon substrate (not shown) instead of the SOI substrate is used, an inactive region may be formed in a region of the silicon substrate, thereby forming the active silicon layer 310.

Referring to FIGS. 2 and 3B, a gate insulating layer 315 is formed on the active silicon layer 310 (S23). The gate insulating layer 315 is formed by forming the gate insulating layer 315 on a region of the active silicon layer 310 using a mask (for example, a fine metal mask) or by forming the gate insulating layer 315 on the entire surface of the active silicon layer 310 and then patterning. The gate insulating layer 315 may be formed of a silicon oxide layer using a thermal oxidation method, or a high-k dielectric layer (for example, HFO₂, HFOₓN_{y}, Ta₂O₅, Al₂O₃, or ZrO₃). Next, a gate electrode 320 is formed on the gate insulating film 315 (S24). The gate electrode 320 is formed of polysilicon or various metals (for example, TiN, W, ErSi, PtSi, and PdSi).

In the next step, Step 25 of FIG. 2 and FIG. 3C are referred. Insulating sidewall spacers 325 are formed on both sidewalls of the gate insulating layer 315 and the gate electrode 320 (S25). The insulating sidewall spacers 325 remain only on the sidewalls of the gate insulating layer 315 and the gate electrode 320 by depositing and then etching (for example, isotropic dry etching) an insulating material on the active silicon layer 310, the gate insulating layer 315, and the gate electrode 320 of FIG. 3B. In this embodiment, the insulating material for forming the sidewall spacers 325 employs a silicon oxide layer.

Referring to FIGS. 2 and 3D, ions are implanted into the active silicon layer 310 having the sidewall spacers 325 (S26). In the step of implanting the ions into the active silicon layer 310 using an ion implantation method, different ions are implanted depending on an N-type device (N-type transistor) and a P-type device (P-type transistor). When the N-type device is manufactured, one of erbium (Er), ytterbium (Yr), samarium (Sm), and yttrium (Y) is implanted into the source and drain regions of the active silicon layer 310. When the P-type device is manufactured, platinum (Pt) atoms are implanted into the source and drain regions. However, when the N-type device is manufactured, a P-type device region to be formed on the substrate 300 is completely blocked, and when the P-type device is manufactured, an N-type device region to be formed on the substrate 300 is completely blocked. After that, ions suitable to characteristics of each device should be implanted.

Next, referring to Step 27 of FIG. 2 and FIG. 3E, the ion-implanted silicon layer 310 is annealed. Even when the ion-implanted silicon layer 310 is annealed, the substrate 300 may be annealed at different temperature conditions depending on the kind of the implanted ion (that is, depending on whether the N-type device or the P-type device is formed). When the N-type device is manufactured, it is annealed at a temperature of about 500° C. to 600° C., and when the P-type device is manufactured, it is annealed at a temperature of about 400° C. to 600° C. In other words, the P-type device can be annealed at a lower temperature than the N-type device. Upon completion of the annealing in Step 27, the metal-silicides different from each other are formed depending on the implanted ions.

In other words, when the N-type transistor is manufactured, erbium (Er) ions are implanted into the silicon layer for manufacturing the N-type transistor and then the silicon layer is annealed so that the source and drain regions of the silicon layer changes into erbium-silicide. When the erbium-silicide is formed by the above-described process, erbium (Er) having a relatively low work function can be prevented from being oxidized, and the Schottky barrier tunnel transistor can have an excellent short channel effect compared to a conventional Schottky barrier transistor due to a Schottky barrier provided between the silicon layer and the erbium-silicide. Of course, when the P-type transistor is manufactured, ions suitable to the P-type device are implanted and annealing is performed at a temperature suitable to the implanted ions, thereby manufacturing a Schottky barrier tunnel transistor having an excellent short channel effect.

As described above, in the present invention, metal ions having a low work function are implanted into silicon through ion implantation capable of easily securing high purity, and then the annealing is performed, thereby forming silicide for manufacturing a device having a low Schottky barrier.

Further, the present invention provides a high-performance Schottky barrier tunnel transistor that includes metal-silicide obtained by implanting ions into a silicon substrate using an ion implantation method and then annealing the ion-implanted silicon layer, is not easily oxidized and more improved in reliability, and can apply to a nano field.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method of manufacturing a Schottky barrier tunnel transistor, the method comprising the steps of:
preparing a substrate;
forming an active silicon layer on the substrate;
forming a gate insulating layer on a region of the silicon layer;
forming a gate electrode on the gate insulating layer;
implanting ions into the silicon layer on which the gate insulating layer is not formed; and
annealing the ion-implanted silicon layer.

2. The method according to claim 1, further comprising the step of, after forming the gate insulating layer, forming sidewall spacers on sidewalls of the gate insulating layer and the gate electrode.

3. The method according to claim 1, wherein, in the step of implanting the ions into the silicon layer, one of erbium (Er), ytterbium (Yr), samarium (Sm), and yttrium (Y) is implanted when an N-type device is manufactured.

4. The method according to claim 3, wherein the annealing is performed at a temperature of about 500° C. to 600° C.

5. The method according to claim 1, wherein, in the step of implanting the ions into the silicon layer, platinum (Pt) is implanted when a P-type device is manufactured.

6. The method according to claim 5, wherein the annealing is performed at a temperature of about 400° C. to 600° C.

7. The method according to claim 2, wherein the silicon layer is formed to a thickness of about 50 nm or less.

8. The method according to claim 1, wherein the substrate is a silicon on insulator (SOI) substrate or a bulk silicon substrate.

9. The method according to claim 8, wherein the substrate is a substrate having a low concentration of about 10¹⁷ cm⁻³ or less.

10. A Schottky barrier tunnel transistor comprising:
an active silicon layer formed on a silicon substrate, and having source and drain regions formed of metal-silicide using ion implantation and a channel region between the source and regions;
a gate insulating layer formed on the active silicon layer; and
a gate electrode formed on the gate insulating layer.

11. The Schottky barrier tunnel transistor according to claim 10, wherein the metal-silicide of the source and regions is formed by implanting different ions depending on an N-type device or a P-type device.

12. The Schottky barrier tunnel transistor according to claim 10, further comprising sidewall spacers formed on sidewalls of the gate insulating layer and the gate electrode.
